(19) United States
(12) Patent Application Publication
(10) Pub. No.: US 2026/0247898 A1
(43) Pub. Date: Aug. 20, 2026

(54) SUBSTRATE CLEANING DEVICE AND SUBSTRATE CLEANING METHOD

(71) Applicant: SCREEN HOLDINGS CO., LTD., Kyoto (JP)

(72) Inventors: Ryohei HOKAKU, Kyoto-shi, Kyoto (JP); Katsunori TANAKA, Kyoto-shi, Kyoto (JP); Wataru YANO, Kyoto-shi, Kyoto (JP)

(21) Appl. No.: 19/099,402

(22) PCT Filed: Jul. 10, 2023
(86) PCT No.: PCT/JP2023/025453

§ 371 Date: Jan. 28, 2025

(30) Foreign Application Priority Data
Jul. 28, 2022 (JP) 2022-120855

(51) Int. Cl. H10P 72/00

(52) U.S. Cl. CPC H10P 72/0412; H10P 72/0414

(57) ABSTRACT

A substrate cleaning device includes a spin chuck, a liquid supply mechanism, a brush pressing mechanism and a brush. The spin chuck rotates a substrate while holding the substrate. The liquid supply mechanism supplies a cleaning liquid onto one surface of the substrate held and rotated by the spin chuck. The brush pressing mechanism presses the brush against the one surface of the rotating substrate during a predetermined pressing period. The liquid supply mechanism supplies the cleaning liquid onto the one surface of the substrate at a predetermined reference flow rate before the pressing period. Further, the liquid supply mechanism supplies the cleaning liquid onto the one surface of the substrate at a flow rate smaller than the reference flow rate or stops supplying the cleaning liquid during at least part of the pressing period.

### TECHNICAL FIELD

The present invention relates to a substrate cleaning device and a substrate cleaning method of cleaning a substrate using a brush.

### BACKGROUND ART

A substrate processing apparatus is used to perform various processes on various substrates such as a substrate for an FPD (Flat Panel Display) that is used for a liquid crystal display device, an organic EL (Electro Luminescence) display device or the like, a semiconductor substrate, a substrate for an optical disc, a substrate for a magnetic disc, a substrate for a magneto-optical disc, a substrate for a photomask, a ceramic substrate or a substrate for a solar cell. A substrate cleaning device is used to clean a substrate.

As one example of the substrate cleaning device, Patent Document 1 describes a substrate processing apparatus that cleans a main surface of a substrate using a brush. Specifically, in the substrate processing apparatus, a processing liquid is supplied to the main surface (upper surface) of the substrate which is held to be rotated by a spin chuck. In this state, the brush is pressed against the main surface of the substrate. Further, the brush moves on the main surface of the substrate in a direction directed from a rotation center of the substrate toward an outer peripheral end of the substrate. Thus, the main surface of the substrate is cleaned.
[Patent Document 1 ]JP 6968547 B2

### SUMMARY OF INVENTION

### Technical Problem

In a substrate cleaning device that cleans one surface of a substrate using a brush, similarly to the substrate processing apparatus according to Patent Document 1, it is desired to improve the cleanliness of the one surface of the substrate after cleaning. Further, in the substrate cleaning device, it is desired to reduce an amount of the processing liquid (cleaning liquid) to be used for cleaning the substrate.

An object of the present invention is to provide a substrate cleaning device and a substrate cleaning method that enable improvement of cleanliness of one surface of a substrate after cleaning using a brush and a reduction in consumption of a cleaning liquid to be used for cleaning the one surface of the substrate.

### Solution to Problem

A substrate cleaning device according to one aspect of the present invention that cleans one surface of a substrate, includes a rotation holder that rotates the substrate while holding the substrate, a liquid supplier that supplies a cleaning liquid onto the one surface of the substrate held and rotated by the rotation holder, a brush, and a brush pressing mechanism that presses the brush against the one surface of the substrate held and rotated by the rotation holder during a predetermined pressing period, wherein the liquid supplier supplies the cleaning liquid onto the one surface of the substrate at a predetermined reference flow rate before the pressing period, and supplies the cleaning liquid onto the one surface of the substrate at a flow rate smaller than the reference flow rate or stops supplying the cleaning liquid during at least part of the pressing period.

A substrate cleaning method according to another aspect of the present invention of cleaning one surface of a substrate, including the steps of rotating the substrate while holding the substrate using a rotation holder, supplying a cleaning liquid onto the one surface of the substrate held and rotated by the rotation holder, and pressing a brush against the one surface of the substrate held and rotated by the rotation holder during a predetermined pressing period, wherein the step of supplying a cleaning liquid includes supplying the cleaning liquid onto the one surface of the substrate at a predetermined reference flow rate before the pressing period, and supplying the cleaning liquid onto the one surface of the substrate at a flow rate smaller than the reference flow rate or stopping supplying the cleaning liquid during at least part of the pressing period.

### Advantageous Effects of Invention

With the present invention, it is possible to improve cleanliness of one surface of a substrate after cleaning using a brush and reduce consumption of a cleaning liquid to be used for cleaning the one surface of the substrate.

### BRIEF DESCRIPTION OF THE DRAWINGS

FIG. 1 is a schematic side view showing one example of the configuration of a substrate cleaning device according to one embodiment of the present invention.

FIG. 2 is a schematic side view showing one example of the state of a spin chuck and its peripheral members when one surface of a substrate is cleaned in the substrate cleaning device of FIG. 1.

FIG. 3 is a diagram for explaining a mechanism in which cleaning power of a brush for the substrate changes in accordance with a thickness of a boundary liquid layer.

FIG. 4 is a diagram for explaining the mechanism in which the cleaning power of the brush for the substrate changes in accordance with the thickness of the boundary liquid layer.

FIG. 5 is a diagram for explaining the mechanism in which the cleaning power of the brush for the substrate changes in accordance with the thickness of the boundary liquid layer.

FIG. 6 is a diagram for explaining a first cleaning example for the one surface of the substrate by the substrate cleaning device of FIG. 1.

FIG. 7 is a diagram for explaining a second cleaning example for the one surface of the substrate by the substrate cleaning device of FIG. 1.

FIG. 8 is a diagram for explaining a third cleaning example for the one surface of the substrate by the substrate cleaning device of FIG. 1.

FIG. 9 is a diagram for explaining a fourth cleaning example for the one surface of the substrate by the substrate cleaning device of FIG. 1.

FIG. 10 is a diagram for explaining a fifth cleaning example for the one surface of the substrate by the substrate cleaning device of FIG. 1.

### DESCRIPTION OF EMBODIMENTS

A substrate cleaning device and a substrate cleaning method including the substrate cleaning device according to embodiments of the present invention will be described below with reference to the drawings. In the following description, a substrate refers to a semiconductor substrate (wafer), a substrate for an FPD (Flat Panel Display) such as a liquid crystal display device or an organic EL (Electro Luminescence) display device, a substrate for an optical disc, a substrate for a magnetic disc, a substrate for a magneto-optical disc, a substrate for a photomask, a ceramic substrate, a substrate for a solar battery, or the like. Further, in the following description, one surface of a substrate is a non-circuit forming surface (back surface), and another surface of the substrate is a circuit forming surface (main surface). Further, the substrate has a circular shape except for a notch.

Further, in the following description, the term “horizontal” means “substantially horizontal.” Strictly speaking, the term “horizontal” in the following description includes a case in which a subject surface or a subject line is parallel to a predetermined horizontal plane and a case in which a subject surface or a subject line is inclined within a certain angler range (an angler range of 10°, for example) with respect to the predetermined horizontal plane. Further, the term “vertical” means “substantially vertical.” Strictly speaking, the term “vertical” in the following description includes a case in which a subject surface or a subject line is parallel to a predetermined vertical plane and a case in which a subject surface or a subject line is inclined within a certain angler range (an angler range of 10°, for example) with respect to the predetermined vertical plane.

### 1. Configuration of Substrate Cleaning Device

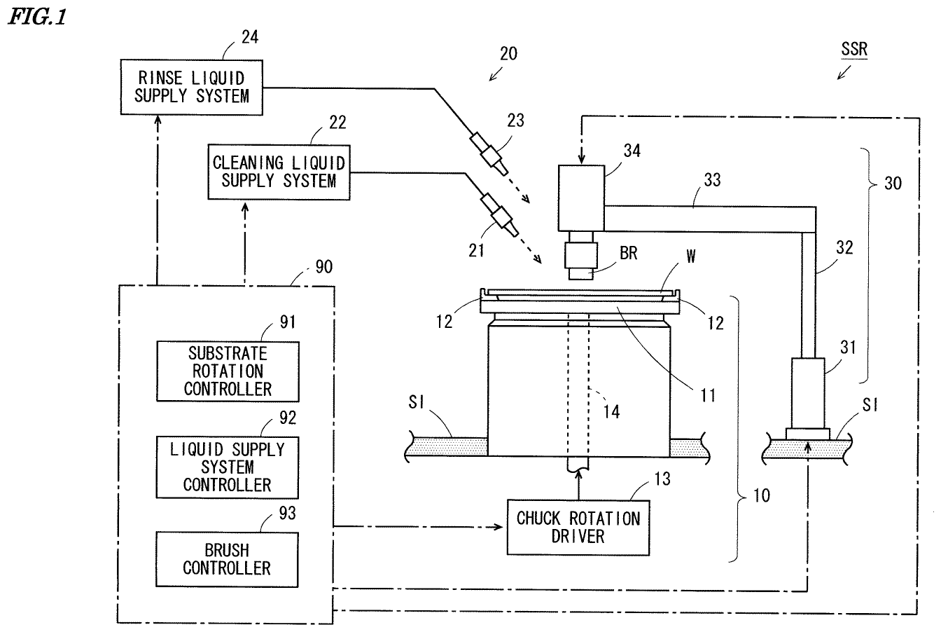

FIG. 1 is a schematic side view showing one example of the configuration of a substrate cleaning device according to one embodiment of the present invention. As shown in FIG. 1, the substrate cleaning device SSR according to the present embodiment includes a spin chuck 10, a liquid supply mechanism 20, a brush pressing mechanism 30, a controller 90 and a brush BR. The spin chuck 10 is a mechanical chuck type spin chuck that holds an outer peripheral end of the substrate W, and includes a spin base 11, a plurality of chuck pins 12, a chuck rotation driver 13 and a rotation shaft 14.

The spin base 11 is a disc-shaped member having a circular shape and a predetermined thickness. The plurality of chuck pins 12 are arranged at equal intervals on the peripheral portion of the upper surface of the spin base 11. Each chuck pin 12 is a rotary holding pin configured to be rotatable about an axis extending in the vertical direction. Each of the plurality of chuck pins 12 rotates with the substrate W arranged on the spin base 11. Thus, the plurality of chuck pins 12 respectively abut against a plurality of portions of the outer peripheral end of the substrate W, so that the substrate W is held.

The chuck rotation driver 13 includes a motor. The rotation shaft 14 is a rotation shaft of the motor of the chuck rotation driver 13. The chuck rotation driver 13 is provided on an installation surface SI such that the rotation shaft 14 extends upwardly. The spin base 11 is fixed to the upper end of the rotation shaft 14 in a horizontal attitude. The chuck rotation driver 13 operates with the substrate W held on the spin base 11. Thus, the substrate W rotates about the rotation shaft 14 extending in the vertical direction.

The brush pressing mechanism 30 is provided at a position close to the spin chuck 10. The brush pressing mechanism 30 includes an arm driver 31, a rotation shaft 32, an arm 33 and a brush driver 34. The arm driver 31 is attached onto the installation surface SI. The arm driver 31 includes a motor and a lifting-lowering device. The rotation shaft 32 is provided to extend upwardly from the arm driver 31 and is supported by the motor of the arm driver 31 so as to be rotatable about an axis extending in the vertical direction. Further, the rotation shaft 32 is supported by the lifting-lowering device of the arm driver 31 so as to be liftable and lowerable.

The arm 33 is coupled to the upper end portion of the rotation shaft 32 so as to extend in a horizontal direction. The brush driver 34 is provided at the tip of the arm 33. The brush BR is provided at the lower end of the brush driver 34. The brush BR is formed of a porous PVA (polyvinyl alcohol) sponge or a PVA sponge in which abrasive grains are dispersed, for example, and has a cleaning surface that can come into contact with the one surface of the substrate W.

The brush driver 34 includes a motor and a pressing device. The brush BR is supported by the motor of the brush driver 34 so as to be rotatable about an axis extending in the vertical direction. Further, the brush BR is supported by the pressing device of the brush driver 34 such that the cleaning surface of the brush driver 34 can be pressed against the one surface of the substrate W with a predetermined pressure when the one surface of the substrate W is cleaned, described below.

In the brush pressing mechanism 30 having the above-mentioned configuration, the arm 33 is rotated in a horizontal plane by an operation of the motor of the arm driver 31. Thus, the brush BR provided at the brush driver 34 moves between a position above the spin chuck 10 and a position outside of and above the spin chuck 10. Further, the arm 33 is lifted or lowered by an operation of the lifting-lowering device of the arm driver 31. Thus, the brush BR provided at the brush driver 34 is lifted or lowered together with the arm 33.

A liquid supply mechanism 20 is provided in association with the spin chuck 10. The liquid supply mechanism 20 includes a cleaning liquid nozzle 21, a cleaning liquid supply system 22, a rinse liquid nozzle 23 and a rinse liquid supply system 24. The cleaning liquid supply system 22 includes fluid-related elements such as a pipe, a pump and a valve, and supplies a cleaning liquid from a cleaning liquid supply source (not shown) to the cleaning liquid nozzle 21. In this case, the cleaning liquid is discharged from the cleaning liquid nozzle 21. In the present embodiment, as the cleaning liquid, a chemical liquid such as BHF (Buffered Hydrofluoric Acid), DHF (Dilute Hydrofluoric Acid), hydrofluoric acid, hydrochloric acid, sulfuric acid, nitric acid, phosphoric acid, acetic acid, oxalic acid or ammonia is used. Further, as the cleaning liquid, a mixed solution (SC1) of ammonia and a hydrogen peroxide solution, a mixed solution (SC2) of hydrochloride and a hydrogen peroxide solution (SC2), or the like can be used as another chemical liquid. As the cleaning liquid, carbonated water, ozone water, hydrogen water, electrolytic ion water, a mixed liquid of any of the above-mentioned chemical liquids and pure water, or the like may be used instead of the above-mentioned chemical liquid.

The rinse liquid nozzle 23 includes fluid-related elements such as a pipe, a pump and a valve, and supplies the cleaning liquid from a rinse liquid supply source (not shown) to the rinse liquid nozzle 23. In this case, the rinse liquid is discharged from the rinse liquid nozzle 23. In the present embodiment, pure water, for example, is used as the rinse liquid. As the rinse liquid, carbonated water, ozone water, hydrogen water, electrolytic ion water or the like may be used instead of pure water, or an organic solvent such as hydrofluoroether (HFE) or isopropyl alcohol (IPA) may be used.

The controller 90 includes a CPU (Central Processing Unit) and a memory, or a microcomputer, for example. The memory stores a substrate cleaning program. The controller 90 includes a substrate rotation controller 91, a liquid supply system controller 92 and a brush controller 93 as functions. These functions are implemented by execution by the CPU of the controller 90 of the substrate cleaning program stored in the memory. Part or all of the functions of the controller 90 may be implemented by hardware such as an electronic circuit.

The substrate rotation controller 91 mainly controls an operation of the chuck rotation driver 13 in a period from the time when the substrate W is carried into the substrate cleaning device SSR until the time when the substrate W is carried out from the substrate cleaning device SSR. The liquid supply system controller 92 mainly controls operations of the cleaning liquid supply system 22 and the rinse liquid supply system 24 during cleaning for the one surface of the substrate W. The brush controller 93 mainly controls operations of the arm driver 31 and the brush driver 34 during cleaning for the one surface of the substrate W.

A basic operation in the above-mentioned substrate cleaning device SSR will be described. Suppose that, in an initial state, the brush BR is held at a waiting position close to the spin chuck 10. First, the substrate W having one surface (back surface) facing upwardly is carried into the substrate cleaning device SSR in a horizontal attitude. The substrate W that has been carried into the substrate cleaning device SSR is held by the spin chuck 10 with the one surface of the substrate W facing upwardly. Further, the substrate W is rotated at a predetermined rotation speed by an operation of the chuck rotation driver 13.

Next, the cleaning liquid is supplied from the cleaning liquid supply system 22 to the rotation center of the rotating substrate W through the cleaning liquid nozzle 21. Thus, the cleaning liquid that has been supplied onto the substrate W spreads over the entire one surface of the substrate W due to a centrifugal force, and a liquid film is formed on the substrate W. In other words, the entire one surface of the substrate W is wetted by the cleaning liquid.

Next, the brush pressing mechanism 30 operates with the supply of the cleaning liquid to the substrate W being continued or stopped. Thus, the brush BR held at the waiting position moves to a position above the rotation center of the substrate W. Further, the brush BR rotates about the axis extending in the vertical direction, and the cleaning surface of the brush BR is pressed against the rotation center of the one surface of the substrate W with a predetermined pressure. Thereafter, on the one surface of the substrate W, the brush BR moves from the rotation center of the substrate W toward the outer peripheral end of the substrate W. Thus, the one surface of the substrate W is physically cleaned by the brush BR.

Next, the rinse liquid is supplied onto the one surface of the rotating substrate W. Further, the brush BR is returned to the waiting position. After the rinse liquid is supplied to the one surface of the substrate W for a certain period, the supply of the rinse liquid to the substrate W is stopped. Thereafter, the substrate W is rotated at a high speed. Thus, liquid droplets of the rinse liquid adhering to the substrate W are shaken off, and the substrate W is dried. Finally, the rotation of the substrate W is stopped, and the dried substrate W after cleaning is carried out of the substrate cleaning device SSR.

### 2. Study in Regard to Improvement of Cleaning Power of Brush BR

In the field of a cleaning method of cleaning the one surface of the substrate W using the brush BR, it is known that the cleaning power of the brush BR for the substrate W (ability to remove contaminants from the substrate W) varies in accordance with the pressing force of the brush BR against the one surface of the substrate W.

Normally, the higher the pressing force of the brush BR with respect to the one surface of the substrate W, the larger the cleaning power of the brush BR for the substrate W, and the lower the pressing force of the brush BR with respect to the one surface of the substrate W, the smaller the cleaning power of the brush BR for the substrate W. Therefore, in a case in which the one surface of the substrate W is cleaned using the brush BR, it is considered that the cleanliness of the substrate W after cleaning is improved when the cleaning surface of the brush BR is pressed against the one surface of the substrate W with a higher pressure.

However, when the pressing force of the brush BR against the one surface of the substrate W is excessively high, the substrate W may be deformed or damaged depending on the size, thickness and the like of the substrate W. Therefore, there is a limit to the cleaning power that can be improved only by an increase in pressing force of the brush BR. Further, the inventors of the present invention cleaned a plurality of substrates W with the brush BR with a plurality of different pressing forces. Thereafter, a test was conducted to measure the cleanliness of the plurality of substrates W cleaned with the different pressing forces. As a result, it was confirmed that, when the pressing force exceeds a certain range, the cleanliness of the cleaned substrate W does not change significantly even in a case in which the magnitude of the pressing force changes.

In consideration of these points, the inventors of the present invention have studied conditions for improving the cleaning power for the substrate W regardless of a pressing force. During cleaning for the one surface of the substrate W using the brush BR, the one surface of the substrate W needs to be wetted with a cleaning liquid such that the one surface of the substrate W is not to be damaged when the brush BR comes into contact with the substrate W.

Conventionally, it is considered that, during cleaning for the substrate W by the brush BR, in a case in which an area where the thickness of a liquid film of a processing liquid (cleaning liquid) is small is present on the substrate W, contaminants that have been removed by the brush BR remain on the substrate W, and the cleanliness of the substrate W is degraded. Therefore, Patent Document 1 proposes a method of not only simply wetting the main surface of the substrate W but also suppressing a decrease in film thickness of the processing liquid (cleaning liquid) formed on the main surface of the substrate W during cleaning for the substrate W by the brush BR.

In contrast, the inventors of the present invention have studied the mechanism of cleaning the substrate W by the brush BR, and have consequently considered that the cleaning power for the substrate W may be degraded when the thickness of the liquid film of the cleaning liquid formed on the substrate W during cleaning for the substrate W by the brush BR is large.

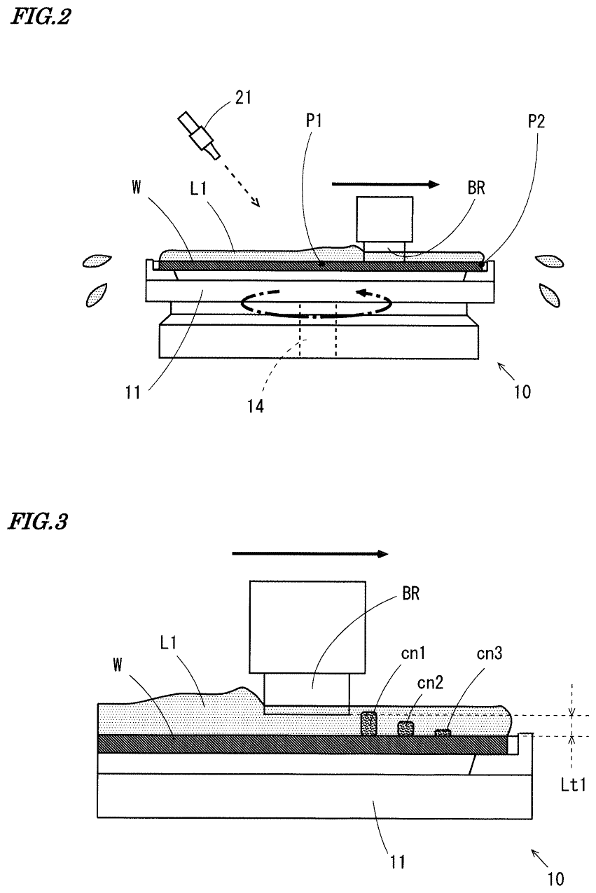

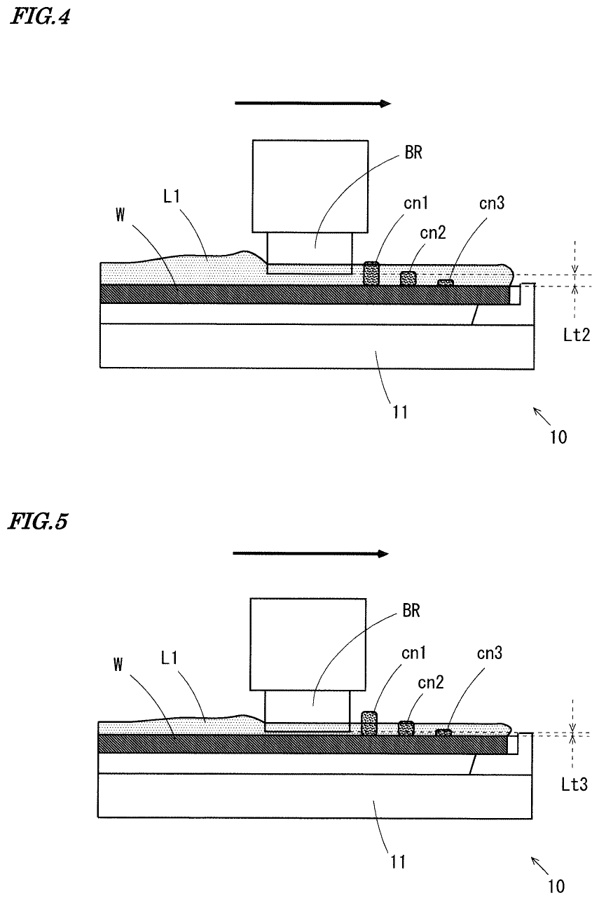

FIG. 2 is a schematic side view showing one example of the state of the spin chuck 10 and its peripheral members when one surface of the substrate W is cleaned in the substrate cleaning device SSR of FIG. 1. In each of the schematic side views shown in FIG. 2, and FIGS. 3 to 10, described below, hatching is applied to the substrate W held by the spin chuck 10 in order to facilitate understanding of the positional relationship between the brush BR and the substrate W, and the like. Further, the dotted pattern is applied to the liquid film of the cleaning liquid or the rinse liquid formed on the substrate W when the cleaning liquid or the rinse liquid is supplied onto the substrate W.

As indicated by the thick one-dot and dash arrow in FIG. 2, during cleaning for the one surface of the substrate W, the rotation shaft 14 of the spin chuck 10 rotates, and the substrate W rotates in a horizontal attitude, for example. In this state, the cleaning liquid is supplied to the position of the rotation center of the substrate W (hereinafter referred to as a rotation center position P1) from the cleaning liquid nozzle 21. Thus, a liquid film L1 of the cleaning liquid is formed on the one surface of the rotating substrate W. Although the liquid film L1 shown in FIG. 2 has substantially the same film thickness over the entire substrate W, in a case in which the substrate W is rotating, the farther a position in the substrate W is separated from the rotation center position P1 in the radial direction of the substrate W, the smaller the thickness of the liquid film L1 actually is.

The cleaning surface of the brush BR is pressed against the one surface of the substrate W with the liquid film L1 formed on the one surface of the substrate W. At this time, the cleaning surface of the brush BR rotates about the axis extending in the vertical direction and is pressed against the one surface of the substrate W with a predetermined pressure. Further, as indicated by the thick solid arrow in FIG. 2, the brush BR is moved from the rotation center position P1 toward a position of the outer peripheral end of the substrate W (hereinafter referred to as an outer peripheral end position P2) on the one surface of the substrate W. At this time, the cleaning surface of the brush BR moves while being in contact with the one surface of the substrate W, whereby contaminants fixed to the one surface of the substrate W are stripped by the brush BR and washed away by the cleaning liquid.

Here, the substrate W rotates during cleaning for one surface of the substrate W. On the other hand, the brush BR moves on the one surface of the substrate W through a linear or arcuate path from the rotation center position P1 of the substrate W to the outer peripheral end position P2 of the substrate W. Further, the brush BR rotates about the axis extending in the vertical direction independently of the rotation of the substrate W. Thus, during cleaning for the one surface of the substrate W by the brush BR, the cleaning surface of the brush BR and the one surface of the substrate W facing each other relatively move and rotate.

In this case, when the cleaning liquid flows into the boundary portion between the cleaning surface of the brush BR and the one surface of the substrate W. At this time, in a case in which the cleaning liquid does not smoothly flow in the boundary portion due to a so-called water drainage failure, a layer of the cleaning liquid is formed between the cleaning surface of the brush BR and the one surface of the substrate W. Such a phenomenon is known as a hydroplaning phenomenon. In the following description, a layer of the cleaning liquid that is formed between the cleaning surface of the brush BR and the one surface of the substrate W when hydroplaning occurs is referred to as a boundary liquid layer.

It is considered that, when the boundary liquid layer is formed due to an occurrence of hydroplaning during the cleaning for the one surface of the substrate W by the brush BR, it is difficult to physically remove, by the brush BR, the contaminants having a size smaller than the thickness of the boundary liquid layer. As such, the inventors of the present invention have estimated a mechanism in which the cleaning power of the brush BR for the substrate W changes in accordance with the thickness of the boundary liquid layer formed during cleaning for the one surface of the substrate W by the brush BR.

FIGS. 3 to 5 are diagrams for explaining the mechanism in which the cleaning power of the brush BR for the substrate W changes in accordance with the thickness of the boundary liquid layer. As shown in FIGS. 3 to 5, suppose that three contaminants cn1, cn2, cn3 having different sizes in the vertical direction are fixed on the one surface of the substrate W.

When a relatively large amount of the cleaning liquid is supplied onto the one surface of the substrate W during the cleaning for the one surface of the substrate W by the brush BR, the liquid film L1 formed on the substrate W increases as shown in the example of FIG. 3. It is estimated that, when hydroplaning occurs in this state, an amount of the cleaning liquid flowing into the space between the cleaning surface of the brush BR and the one surface of the substrate W per unit time increases, and the thickness Lt1 of the boundary liquid layer increases. In this case, when the brush BR moves on the substrate W, the cleaning surface of the brush BR comes into contact with the contaminants cn1 having a size larger than the thicknesses Lt1. However, the cleaning surface of the brush BR does not come into contact with the contaminants cn2, cn3 having sizes smaller than the thickness Lt1. Thus, the contaminants cn2, cn3 having sizes smaller than the thickness Lt1 are not removed by the brush BR.

On the other hand, when a medium amount of the cleaning liquid is supplied onto the one surface of the substrate W during the cleaning for the one surface of the substrate W by the brush BR, the thickness of the liquid film L1 formed on the substrate W slightly decreases as compared with the example of FIG. 3. When hydroplaning occurs in this state, an amount of the cleaning liquid flowing into the space between the cleaning surface of the brush BR and the one surface of the substrate W per unit time relatively decreases, and the thickness Lt2 of the boundary liquid layer is estimated to slightly decreases as compared with the example of FIG. 3. In this case, when the brush BR moves on the substrate W, the cleaning surface of the brush BR comes into contact with the contaminants cn1, cn2 having sizes larger than the thicknesses Lt2. However, the cleaning surface of the brush BR does not come into contact with the contaminants cn3 having a size smaller than the thicknesses Lt2. Thus, the contaminants cn3 having a size smaller than the thicknesses Lt2 are not removed by the brushes BR.

On the other hand, as shown in the example of FIG. 5, when the cleaning liquid is hardly supplied onto the one surface of the substrate W during the cleaning for the one surface of the substrate W by the brush BR, the thickness of the liquid film L1 formed on the substrate W significantly decreases as compared with the example of FIG. 3. It is estimated that, when hydroplaning occurs in this state, an amount of the cleaning liquid flowing into the space between the cleaning surface of the brush BR and the one surface of the substrate W per unit time significantly decreases, and the thickness Lt3 of the boundary liquid layer sufficiently decreases as compared with the example of FIG. 3. In this case, when the brush BR moves on the substrate W, the cleaning surface of the brush BR comes into contact with the contaminants cn1, cn2, cn3 having sizes larger than the thickness Lt3. Thus, even in a case in which hydroplaning occurs, a large portion of the contaminants on the substrate W are removed.

The inventors of the present inventions have considered that, based on the mechanism estimated as described above, it is possible to improve the cleaning power by reducing an amount of the cleaning liquid to be supplied to the substrate W in the process of pressing the brush BR against the one surface of the substrate W on which the liquid film L1 of the cleaning liquid is formed. Further, the inventors of the present invention have devised a plurality of cleaning examples which are considered to be suitable for improving the cleaning power of the brush BR for the one surface of the substrate W based on the above-mentioned mechanism. The plurality of cleaning examples will be described below.

### 3. First Cleaning Example

In the following description, a period during which a liquid film of the cleaning liquid is formed on the one surface of the rotating substrate W before the brush BR is pressed (a period required for so-called pre-wetting) is referred to as a liquid film formation period. Further, a period during which the brush BR is pressed against the one surface of the rotating substrate W after the liquid film formation period is referred to as a brush pressing movement period. Further, a period during which the rinse liquid is supplied onto the one surface of the rotating substrate W in order to remove the cleaning liquid and contaminants remaining on the one surface of the substrate W after the brush pressing movement period is referred to as a rinsing period. Further, a period during which the substrate W is shaken to be dried by being rotated at a high speed with the supply of the cleaning liquid and the rinse liquid to the substrate W being stopped after the rinsing period is referred to as a drying period.

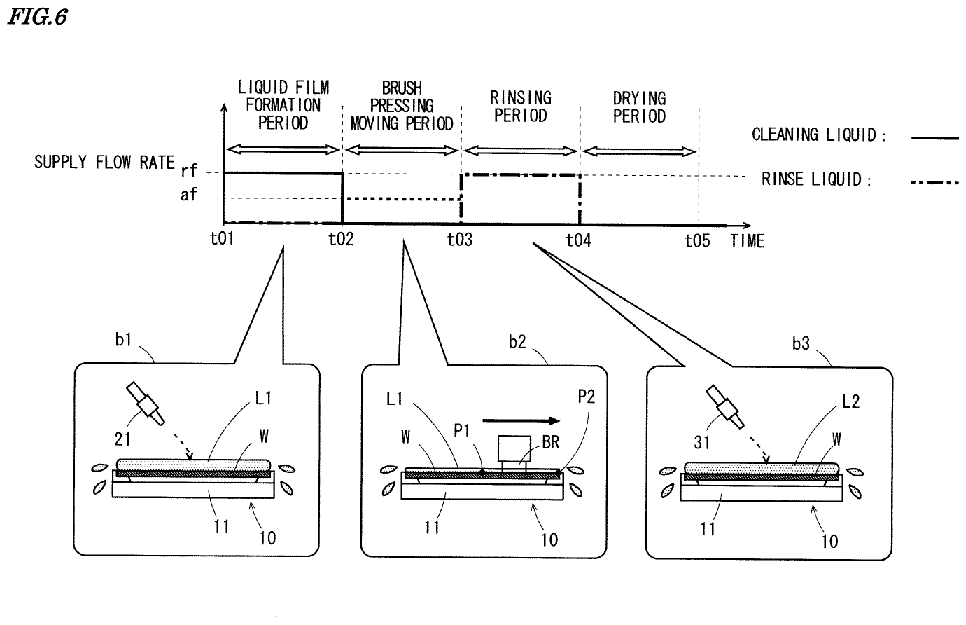

FIG. 6 is a diagram for explaining a first cleaning example for the one surface of the substrate W by the substrate cleaning device SSR of FIG. 1. In the upper field of FIG. 6, the changes of the flow rates of the cleaning liquid and the rinse liquid to be supplied onto the one surface of the substrate W are shown in a time chart in the first cleaning example. In the time chart in the upper field of FIG. 6, the abscissa indicates the time, and the ordinate indicates a supply flow rate. The supply flow rate is an amount of liquid to be supplied to the substrate W per unit time. Further, in the time chart, the thick solid line indicates the temporal change of the flow rate of the cleaning liquid to be supplied from the cleaning liquid nozzle 21 of FIG. 1 to the substrate W, and the thick one-dot and dash line indicates the temporal change of the flow rate of the rinse liquid to be supplied to the substrate W from the rinse liquid nozzle 23 of FIG. 1. In the lower field of FIG. 6, the state of the substrate W and the its peripheral portions in a partial period or at a point in time of the first cleaning example is shown in each of the schematic side views in the plurality of balloons.

In an initial state, the substrate W that has been carried into the substrate cleaning device SSR is held by the spin chuck 10 and is rotated at a predetermined rotation speed. The substrate rotation controller 91 of FIG. 1 controls the chuck rotation driver 13 such that the substrate W is held in a horizontal attitude and rotates at a predetermined rotation speed from a point t01 in time to a point t05 in time, described below. Further, suppose that the brush BR is in the waiting position in the initial state.

As shown in the upper field of FIG. 6, the liquid film formation period is set from the point t01 in time to the point t02 in time. In the liquid film formation period, the liquid supply system controller 92 of FIG. 1 controls the cleaning liquid supply system 22 of FIG. 1 such that the cleaning liquid is supplied to the substrate W at a predetermined reference flow rate rf. Further, the liquid supply system controller 92 controls the rinse liquid supply system 24 of FIG. 1 such that the rinse liquid is not supplied to the substrate W. In consideration of the size of the substrate W and the viscosity of the cleaning liquid, for example, the reference flow rate rf is set such that the liquid film is formed on at least the entire one surface of the substrate W in the predetermined liquid film formation period by an experiment, simulation or the like. Thus, as shown in the balloon b1 in the lower field of FIG. 6, a liquid film L1 of the cleaning liquid is formed on the one surface of the substrate W during the liquid film formation period.

Next, the brush pressing movement period is set from the point t02 in time to a point t03 in time. During the brush pressing movement period, the liquid supply system controller 92 controls the cleaning liquid supply system 22 and the rinse liquid supply system 24 such that the cleaning liquid or the rinse liquid is not supplied to the substrate W.

On the other hand, the brush controller 93 of FIG. 1 controls the arm driver 31 of FIG. 1 such that the brush BR moves from the rotation center position P1 to the outer peripheral end position P2 on the one surface of the substrate W from the point t01 in time to the point t03 in time. Further, the brush controller 93 controls the brush driver 34 of FIG. 1 such that the brush BR rotates about the axis extending in the vertical direction and the cleaning surface of the brush BR is pressed against the one surface of the substrate W with a predetermined pressure. In this case, as shown in the balloon b2 in the lower field of FIG. 6, during the brush pressing movement period, the brush BR is pressed against the one surface of the substrate W with the thickness of the liquid film L1 being smaller than the thickness of the liquid film L1 during the liquid film formation period. Thus, even in a case in which hydroplaning occurs during the brush pressing movement period, the cleaning power for the substrate W is improved as compared with a case in which the flow rate of the cleaning liquid to be supplied to the substrate W is maintained at the reference flow rate rf.

Next, the rinsing period is set from the point t03 in time to a point t04 in time. During the rinsing period, the liquid supply system controller 92 controls the rinse liquid supply system 24 such that the rinsing liquid is supplied to the substrate W at the reference flow rate rf. Further, the liquid supply system controller 92 controls the cleaning liquid supply system 22 such that the rinse liquid is not supplied to the substrate W. In this case, as shown in the balloon b3 in the lower field of FIG. 6, a liquid film L2 of the rinse liquid is formed on the one surface of the substrate W during the rinsing period. The brush controller 93 controls the arm driver 31 such that the brush BR returns to the waiting position during the rinsing period.

Finally, the drying period is set from the point t04 in time to a time t05 in time. During the drying period, the liquid supply system controller 92 controls the cleaning liquid supply system 22 and the rinse liquid supply system 24 such that the cleaning liquid or the rinse liquid is not supplied to the substrate W. Thus, the rinse liquid on the substrate W is shaken off, and the substrate W is dried.

As described above, according to the first cleaning example, the cleaning liquid is not supplied to the substrate W during the brush pressing movement period. Therefore, it suppresses an increase in thickness of the liquid film L1 of the cleaning liquid formed on the substrate W during cleaning for the substrate W by the brush BR. Thus, the cleaning power of the brush BR for the substrate W is improved as compared with a case in which the cleaning liquid is continuously supplied to the substrate W at the reference flow rate rf during the brush pressing movement period.

In the first cleaning example, as indicated by the thick dotted line in the graph in the upper field of FIG. 6, the flow rate of the cleaning liquid to be supplied to the substrate W may be maintained constant at a flow rate af smaller than the reference flow rate rf from the start point t02 in time to the end point t03 in time of the brush pressing movement period. Also in this case, the cleaning power of the brush BR for the substrate W is improved as compared with a case in which the cleaning liquid is continuously supplied to the substrate W at the reference flow rate rf during the brush pressing movement period.

In consideration of the pressing force of the brush BR against the substrate W, the relative speeds of the brush BR and the substrate W relative to each other, the viscosity of the cleaning liquid, and the like, the above-mentioned flow rate af is preferably set such that the thickness of the boundary liquid layer is more appropriate.

Further, in the first cleaning example, the flow rate of the rinse liquid to be supplied to the substrate W during the rinsing period may be smaller than the reference flow rate rf or may be larger than the reference flow rate rf.

### 4. Second Cleaning Example

Differences of a second cleaning example from the first cleaning example will be described. In the following description, a specific position on the path of the brush BR moving from the rotation center position P1 to the outer peripheral end position P2 during the brush pressing movement period is referred to as a specific position.

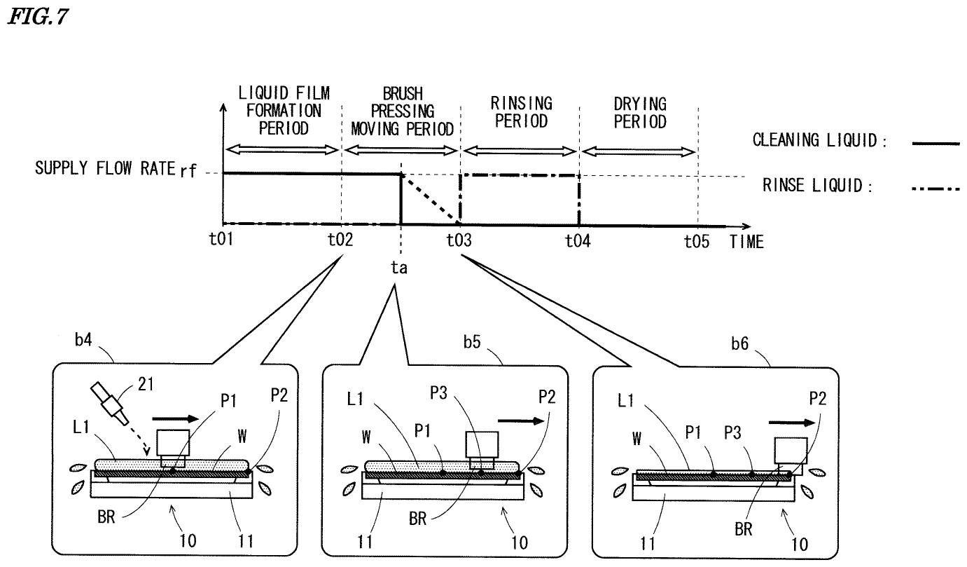

FIG. 7 is a diagram for explaining the second cleaning example for the one surface of the substrate W by the substrate cleaning device SSR of FIG. 1. In the upper field of FIG. 7, similarly to the example of the upper field of FIG. 6, the changes of the flow rates of the cleaning liquid and the rinse liquid to be supplied onto the one surface of the substrate W are shown in a time chart in the second cleaning example. Further, in the lower field of FIG. 7, similarly to the example in the lower field of FIG. 6, the states of the substrate W and the its peripheral portions in a partial period or at a point in time of the second cleaning example is shown in each of the schematic side view in the plurality of balloons.

In the second cleaning example, as shown in the upper field of FIG. 7, the liquid supply system controller 92 controls the cleaning liquid supply system 22 such that the cleaning liquid is continuously supplied to the substrate W at the reference flow rate rf in the period from the point t02 in time to a point ta in time that is earlier than the point t03 in time. Further, the liquid supply system controller 92 controls the rinse liquid supply system 24 such that the rinse liquid is not supplied to the substrate W in the period from the point t02 in time to the point ta in time. Here, the point ta in time is a point in time at which the brush BR reaches the specific position P3 during the brush pressing movement period. In this case, as shown in the balloons b4 and b5 in the lower field of FIG. 7, in a period during which the brush BR moves from the rotation center position P1 to the specific position P3, the brush BR is pressed against the one surface of the substrate W with the liquid film L1 having substantially the same thickness as the thickness of the liquid film L1 during the liquid film formation period.

Thereafter, in the period from the point ta in time to the point t03 in time, the liquid supply system controller 92 controls the cleaning liquid supply system 22 and the rinse liquid supply system 24 such that the cleaning liquid or the rinse liquid is not supplied to the substrate W. In this case, as shown in the balloon b6 in the lower field of FIG. 7, in a period during which the brush BR moves from the specific position P3 to the outer peripheral end position P2, the brush BR is pressed against the one surface of the substrate W with the liquid film L1 having a thickness smaller than the thickness of the liquid film L1 during the liquid film formation period.

Thus, in the period during which the brush BR moves from the specific position P3 to the outer peripheral end position P2, even in a case in which hydroplaning occurs, the cleaning power for the substrate W is improved as compared with a case in which the flow rate of the cleaning liquid to be supplied to the substrate W is maintained at the reference flow rate rf.

As described above, according to the second cleaning example, the cleaning liquid is not supplied to the substrate W in part of the brush pressing movement period. Therefore, it suppresses an increase in thickness of the liquid film L1 of the cleaning liquid formed on the substrate W during the partial period. Thus, the cleaning power of the brush BR for the substrate W is improved in part of the brush pressing movement period. Therefore, it is possible to locally improve the cleaning power of the brush BR in part of the one surface of the substrate W by appropriately defining the specific position P3.

The specific position P3 may be set at an intermediate position between the rotation center position P1 and the outer peripheral end position P2 in the radial direction of the substrate W, for example. Alternatively, the specific position P3 may be set at a position closer to the outer peripheral end of the substrate W than the intermediate position in the radial direction of the substrate W. In these cases, the cleaning power of the brush BR for the substrate W can be improved at least in an area in the vicinity of the outer peripheral end of the substrate W.

In the second cleaning example, as indicated by the thick dotted line in the upper field of FIG. 7, the flow rate of the cleaning liquid to be supplied to the substrate W may be continuously decreased from the point ta in time to the end point t03 in time of the brush pressing movement period. Also in this case, in the period from the point ta to the point t03 in time, the cleaning power of the brush BR for the substrate W is improved as compared with a case in which the cleaning liquid is continuously supplied to the substrate W at the reference flow rate rf during the brush pressing movement period.

### 5. Third Cleaning Example

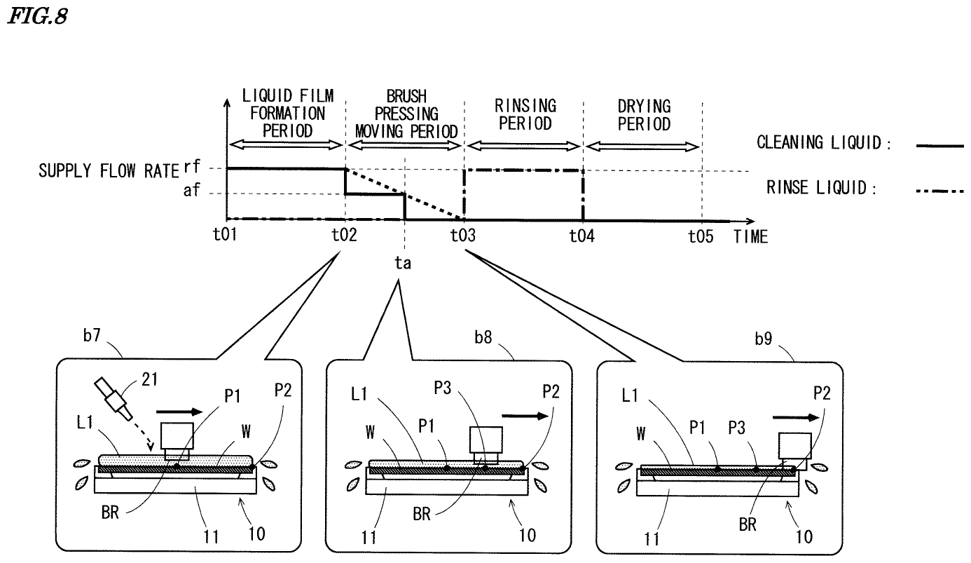

Differences of a third cleaning example from the second cleaning example will be described. FIG. 8 is a diagram for explaining the third cleaning example for the one surface of the substrate W by the substrate cleaning device SSR of FIG. 1. In the upper field of FIG. 8, similarly to the example of the upper field of FIG. 6, the changes of the flow rates of the cleaning liquid and the rinse liquid to be supplied to the one surface of the substrate W are shown in a time chart in the third cleaning example. Further, in the lower field of FIG. 8, similarly to the example in the lower field of FIG. 6, the state of the substrate W and the its periphery in a partial period or at a point in time of the third cleaning example is shown in each of the schematic side views in the plurality of balloons.

In the third cleaning example, as shown in the upper field of FIG. 8, in the period from the point t02 in time to the point ta in time, the liquid supply system controller 92 controls the cleaning liquid supply system 22 such that the cleaning liquid is supplied to the substrate W at the flow rate af that is smaller than the reference flow rate rf. In this case, as shown in the balloons b7 to b9 in the lower field of FIG. 8, in a period during which the brush BR moves from the rotation center position P1 to the specific position P3, the thickness of the liquid film L1 is decreased in steps at the point t02 in time and then at the point ta in time. Thus, the cleaning power of the brush BR for the substrate W is sequentially adjusted in a plurality of areas the radial direction of the substrate W.

In the third cleaning example, as indicated by the thick dotted line in the upper field of FIG. 8, the flow rate of the cleaning liquid to be supplied to the substrate W may be continuously decreased from the start point t02 in time to the end point t03 in time of the brush pressing movement period. Also in this case, the cleaning power of the brush BR for the substrate W is improved as compared with a case in which the cleaning liquid is continuously supplied to the substrate W at the reference flow rate rf during the brush pressing movement period.

### 6. Fourth Cleaning Example

Differences of a fourth cleaning example from the first cleaning example will be described. In the fourth cleaning example, during the cleaning for the one surface of the substrate W by the brush BR, the brush BR moves while being pressed against the one surface of the substrate W multiple times (twice in the present example). Specifically, the brush BR moves from the rotation center position P1 to the outer peripheral end position P2 while being pressed against the one surface of the rotating substrate W. Next, the brush BR moves to a position above the outer peripheral end position P2 so as to be separated from the substrate W, and moves toward a position above the rotation center position P1. When the brush BR reaches the position above the rotation center position P1, the brush BR is again pressed against the one surface of the substrate W. Thereafter, the brush BR moves from the rotation center position P1 to the outer peripheral end position P2 while being pressed against the one surface of the rotating substrate W. In the following description, a period during which the brush BR moves from the outer peripheral end position P2 of the substrate W to the rotation center position P1 of the substrate W while being separated from the substrate W is referred to as a brush separation movement period.

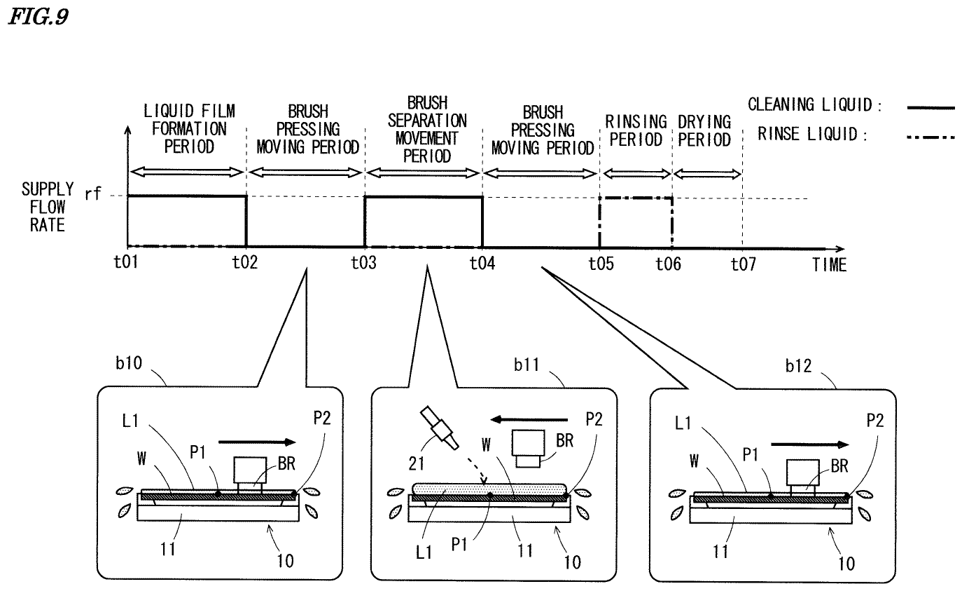

FIG. 9 is a diagram for explaining the fourth cleaning example for the one surface of the substrate W by the substrate cleaning device SSR of FIG. 1. In the upper field of FIG. 9, similarly to the example of the upper field of FIG. 6, the changes of the flow rates of the cleaning liquid and the rinse liquid to be supplied to the one surface of the substrate W are shown in a time chart in the fourth cleaning example. Further, in the lower field of FIG. 9, similarly to the example in the lower field of FIG. 6, the state of the substrate W and the its peripheral portions in a partial period or at a point in time of the fourth cleaning example is shown in each of the schematic side views in the plurality of balloons.

In the fourth cleaning example, as shown in the upper field of FIG. 9, the liquid film formation period, the brush pressing movement period, the brush separation movement period, the brush pressing movement period, the rinsing period and the drying period are set in this order. In this manner, in the fourth cleaning example, two brush pressing movement periods are set to be arranged with the brush separation movement period interposed therebetween on the time axis.

First, in the fourth cleaning example, the same operation as the operation performed in the first cleaning example is performed from the start point t01 in time of the liquid film formation period to the end point t03 in time of the first brush pressing movement period. Thus, the cleaning liquid is not supplied to the substrate W in the first brush pressing movement period. Thus, as shown in the balloon b10 in the lower field of FIG. 9, in a period during which the brush BR is pressed against the one surface of the substrate W, the thickness of the liquid film L1 formed on the one surface of the substrate W can be decreased. Therefore, the one surface of the substrate W is cleaned with high cleaning power.

Next, from the point t03 in time to the point t04 in time, the brush controller 93 controls the arm driver 31 such that the brush BR moves from the outer peripheral end position P2 toward the rotation center position P1 while being separated from the substrate W. At this time, the liquid supply system controller 92 controls the cleaning liquid supply system 22 such that the cleaning liquid is supplied to the substrate W at the reference flow rate rf. Thus, as shown in the balloon b11 in the lower field of FIG. 9, the thickness of the liquid film L1 is increased in a period during which the brush BR is separated from the substrate W. Therefore, even in a case in which remaining on the substrate W, contaminants that have been stripped from the substrate W by the brush BR in the first brush pressing movement period are washed away by a large amount of the cleaning liquid.

Next, when reaching the rotation center position P1 at the point t04 in time, the brush BR is again pressed against the one surface of the substrate W. Further, the same operation (movement of the brush BR) as the operation performed in the first brush pressing movement period is repeated from the point t04 in time to the point t05 in time. Further, the cleaning liquid is not supplied to the substrate W at this time. Thus, as shown in the balloon b12 in the lower field of FIG. 9, in a period during which the brush BR is pressed against the one surface of the substrate W, the liquid film L1 formed on the one surface of the substrate W can be decreased.

Thereafter, the same operation as the operation performed in the rinsing period (the period from the point t03 in time to the point t04 in time in FIG. 6) of the first cleaning example is performed from the point t05 in time to the point t06 in time. Further, the same operation as the operation performed in the drying period of the first cleaning example (the period from the point t04 to the point t05 in time of FIG. 6) is performed from the time t06 to the time t07.

As described above, according to the fourth cleaning example, similarly to the first cleaning example, the cleaning liquid is not supplied to the substrate W during the brush pressing movement period. During cleaning for the substrate W by the brush BR, this suppresses an increase in thickness of the liquid film L1 of the cleaning liquid formed on the substrate W. Thus, the cleaning power of the brush BR for the substrate W is improved as compared with a case in which the cleaning liquid is continuously supplied to the substrate W at the reference flow rate rf during the brush pressing movement period. Further, in the fourth cleaning example, the one surface of the substrate W is repeatedly cleaned by the brush BR multiple times. Therefore, the cleanliness of the one surface of the substrate W after cleaning is further improved.

Further, in the fourth cleaning example, the cleaning liquid is supplied to the substrate W during the brush separation movement period. Therefore, even in a case in which the brush pressing movement period is repeated multiple times with the brush separation movement period interposed therebetween, the one surface of the substrate W is prevented from being dried.

In the example of FIG. 9, as the fourth cleaning example, two brush pressing movement periods are set with one brush separation movement period interposed therebetween on the time axis. However, three, or four or more brush pressing movement periods may be set in the fourth cleaning example. In this case, one brush separation movement period is set between each two adjacent brush pressing movement periods on the time axis. Further, in the fourth cleaning example, during the brush separation movement period, the cleaning liquid may be supplied to the substrate W at a flow rate lower than the reference flow rate rf and higher than 0.

### 7. Fifth Cleaning Example

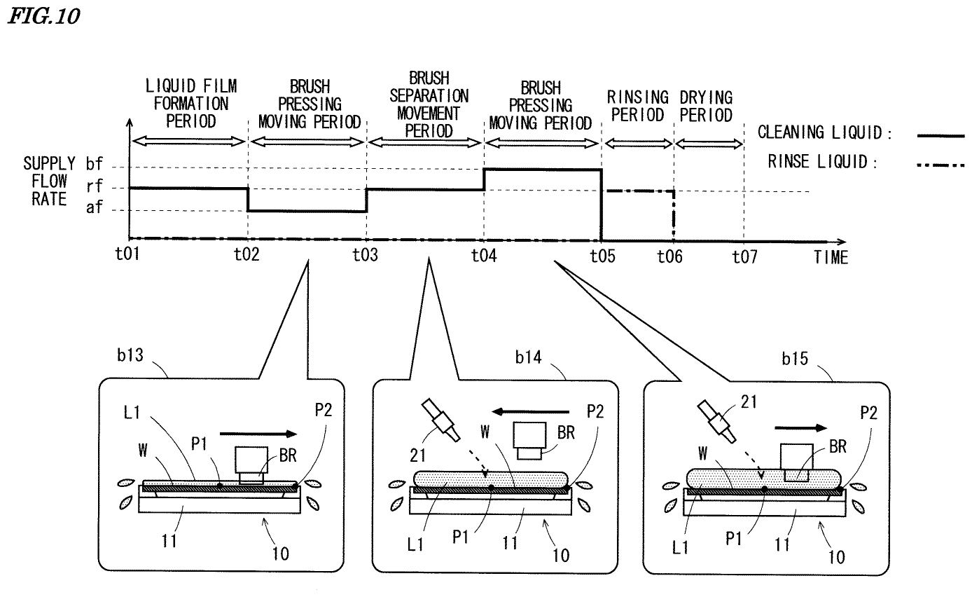

Differences of a fifth cleaning example from the fourth cleaning example will be described. FIG. 10 is a diagram for explaining the fifth cleaning example for the one surface of the substrate W by the substrate cleaning device SSR of FIG. 1. In the upper field of FIG. 10, similarly to the example of the upper field of FIG. 6, the changes of the flow rates of the cleaning liquid and the rinse liquid to be supplied to the one surface of the substrate W are shown in a time chart in the fifth cleaning example. Further, in the lower field of FIG. 10, similarly to the example in the lower field of FIG. 6, the state of the substrate W and the its peripheral portions in a partial period or at a point in time of the fifth cleaning example is shown in each of the schematic side views in the plurality of balloons.

In the fifth cleaning example, as shown in the upper field of FIG. 10, the liquid film formation period, the brush pressing movement period, the brush separation movement period, the brush pressing movement period, the rinsing period and the drying period are set in this order. The setting order of the plurality of periods is the same as that in the fourth cleaning example. However, the fifth cleaning example is different from the fourth cleaning example in that the cleaning liquid is supplied to the substrate W during the first brush pressing movement period and the second brush pressing movement period.

Specifically, in the first brush pressing movement period, the liquid supply system controller 92 controls the cleaning liquid supply system 22 such that the cleaning liquid is supplied to the substrate W at the flow rate af smaller than the reference flow rate rf. Further, in the second brush pressing movement period, the liquid supply system controller 92 controls the cleaning liquid supply system 22 such that the cleaning liquid is supplied to the substrate W at a flow rate bf larger than the reference flow rate rf.

In this case, in the first brush pressing movement period, as shown by the balloon b13 in the lower field of FIG. 10, the thickness of the liquid film L1 is decreased as compared with a case in which the flow rate of the cleaning liquid to be supplied to the substrate W is maintained at the reference flow rate rf. Thus, the cleaning power of the brush BR for the substrate W is improved as compared with a case in which the cleaning liquid is continuously supplied to the substrate W at the reference flow rate rf during the brush pressing movement period.

Thereafter, in the brush separation movement period, as shown by the balloon b14 in the lower field of FIG. 10, the cleaning liquid is supplied to the substrate W at the reference flow rate rf. Therefore, contaminants that have been stripped from the substrate W during the first brush pressing movement period and remain on the substrate W are washed away by the cleaning liquid.

Further, in the second brush pressing movement period, as shown by the balloon b15 in the lower field of FIG. 10, the thickness of the liquid film L1 is further increased as compared with a case in which the flow rate of the cleaning liquid to be supplied to the substrate W is maintained at the reference flow rate rf. Thus, contaminants which have been stripped from the substrate W during the first brush pressing movement period and remain on the substrate W are smoothly washed away by a large amount of cleaning liquid. Further, at this time, contaminants adhering to the brush BR are also washed away by the cleaning liquid.

In the fifth cleaning example, the flow rate of the rinse liquid to be supplied to the substrate W during the brush separation movement period may be larger than the reference flow rate rf or may be smaller than the reference flow rate rf. Further, in the fifth cleaning example, the flow rate bf of the cleaning liquid to be supplied to the substrate W during the second brush pressing movement period is only required to be larger than the flow rate af of the cleaning liquid to be supplied to the substrate W during the first brush pressing movement period. Therefore, the flow rate of the rinse liquid to be supplied to the substrate W during the second brush separation movement period may be larger than the reference flow rate rf or may be smaller than the reference flow rate rf.

### 8. Confirmation Test

The inventors of the present invention conducted a plurality of confirmation tests in order to confirm the relationship between the flow rate of the cleaning liquid to be supplied to the substrate W during the brush pressing movement period and the cleaning power of the brush BR for the substrate W. Each of the plurality of confirmation tests was basically performed in the following flow.

First, a test substrate having a predetermined amount of contaminants attached to one surface thereof was prepared. Subsequently, the test substrate was cleaned by the cleaning method corresponding to each confirmation test using the substrate cleaning device SSR of FIG. 1. Thereafter, how clean each test substrate after cleaning has become as compared with the contaminated test substrate before cleaning was measured as a contamination removal rate. It can be said that the higher the removal rate, the higher the cleaning power of the brush BR for the substrate W, and the cleaner the test substrate after cleaning. This measurement can be performed using a particle counter. The cleaning method corresponding to each confirmation test, and the test results will be described below.

### (a) First Confirmation Test

In a first confirmation test, a film formation period, a brush pressing movement period, a rinsing period and a drying period were set in this order, and a cleaning process of cleaning a test substrate using the brush BR was performed in accordance with the set order. Here, in the first confirmation test, a liquid mixture of a chemical liquid and pure water was supplied as a cleaning liquid onto one surface of the test substrate during the brush pressing movement period. The supply flow rate of the chemical liquid was set to 400 mL/min, and the supply flow rate of the pure water was set to 400 mL/min. Therefore, the supply flow rate (total flow rate) of the liquid mixture of the chemical liquid and the pure water was 800 mL/min.

### (b) Second Confirmation Test

In a second confirmation test, the cleaning process of cleaning a test substrate using the brush BR was performed by the same method as that of the first confirmation test except that the supply flow rates of the chemical liquid and the pure water to be supplied to the test substrate during the brush pressing movement period were different. In the second confirmation test, during the brush pressing movement period, the supply flow rate of the chemical liquid was set to 200 mL/min, and the supply flow rate of the pure water was set to 200 mL/min. Therefore, the supply flow rate (total flow rate) of the liquid mixture of the chemical liquid and the pure water was 400 mL/min.

### (c) Results of First Confirmation Test and Second Confirmation Test

As a result of the first confirmation test, the contamination removal rate measured based on the count of contaminants remaining on the test substrate after cleaning was 71 %. On the other hand, as a result of the second confirmation test, the contamination removal rate measured based on the count of contaminants remaining on the test substrate after cleaning was 82 %. Thus, it was confirmed that the smaller the flow rate of the cleaning liquid (the liquid mixture of the chemical liquid and the pure water in the present case) to be supplied to the test substrate during the brush pressing movement period, the more improved the cleaning power.

### (d) Third confirmation Test

In a third confirmation test, the film formation period, the brush pressing movement period, the rinsing period and the drying period were set in this order, and the cleaning process of cleaning a test substrate using the brush BR was performed in accordance with the set order. Here, in the third confirmation test, a chemical liquid was supplied as a cleaning liquid onto one surface of the test substrate during the brush pressing movement period. The supply flow rate of the chemical liquid was set to 400 mL/min.

### (e) Fourth Confirmation Test

In a fourth confirmation test, the cleaning process of cleaning a test substrate using the brush BR was performed by the same method as that of the third confirmation test except that the supply flow rates of the chemical liquid and the pure water to be supplied to the test substrate during the brush pressing movement period were different. In the third confirmation test, during the brush pressing movement period, the supply flow rate of the chemical liquid was set to 200 mL/min.

### (f) Results of Third Confirmation Test and Fourth Confirmation Test

As a result of the third confirmation test, the contamination removal rate measured based on the count of contaminants remaining on the test substrate after cleaning was 88 %. On the other hand, as a result of the fourth confirmation test, the contamination removal rate measured based on the count of contaminants remaining on the test substrate after cleaning was 91 %. Thus, it was confirmed that the smaller the flow rate of the cleaning liquid (the chemical liquid in the present case) to be supplied to the test substrate during the brush pressing movement period, the more improved the cleaning power.

### (g) Fifth Confirmation Test

In a fifth confirmation test, the film formation period, the brush pressing movement period, the rinsing period and the drying period were set in this order, and the cleaning process of cleaning a test substrate using the brush BR was performed in accordance with the set order. Here, in the fifth confirmation test, a certain amount of a chemical liquid was supplied as a cleaning liquid onto one surface of the test substrate during the brush pressing movement period.

### (h) Sixth Confirmation Test

In a sixth confirmation test, the process of cleaning a test substrate by the brush BR was performed by the same method as that of the fifth confirmation test except that the supply flow rate of the cleaning liquid to be supplied to the test substrate in the middle of the brush pressing movement period was 0.

### (i) Results of Fifth Confirmation Test and Sixth Confirmation Test

As a result of the fifth confirmation test, the contamination removal rate measured based on the count of contaminants remaining on the test substrate after cleaning was 65 %. On the other hand, as a result of the sixth confirmation test, the contamination removal rate measured based on the count of contaminants remaining on the test substrate after cleaning was 74 %. Further, it was confirmed that, in the test substrate according to the sixth confirmation test, an amount of contaminants remaining in an area pressed by the brush BR after the supply of the cleaning liquid was stopped was sufficiently smaller than an amount of contaminants remaining on another area. Thus, it was confirmed that the smaller the flow rate of the cleaning liquid (the chemical liquid in the present case) to be supplied to the test substrate during the brush pressing movement period, the more improved the cleaning power.

### (j) Seventh Confirmation Test

In a seventh confirmation test, the film formation period, the brush pressing movement period, the brush separation movement period, the brush pressing movement period, the rinsing period and the drying period were set in this order, and the cleaning process of cleaning a test substrate using the brush BR was performed in accordance with the set order. Here, in the seventh confirmation test, a certain amount of a chemical liquid was supplied as a cleaning liquid onto one surface of the test substrate during each brush pressing movement period.

### (k) Eighth Confirmation Test

In an eighth confirmation test, the cleaning process of cleaning a test substrate using the brush BR was performed by the same method as that of the seventh confirmation test except that the supply flow rate of the cleaning liquid to be supplied to the test substrate in the middle of each brush pressing movement period was 0.

### (I) Results of Seventh Confirmation Test and Eighth Confirmation Test

As a result of the seventh confirmation test, the contamination removal rate measured based on the count of contaminants remaining on the test substrate after cleaning was 74 %. On the other hand, as a result of the eighth confirmation test, the contamination removal rate measured based on the count of contaminants remaining on the test substrate after cleaning was 80 %. Further, it was confirmed that, in the test substrate according to the eighth confirmation test, an amount of contaminants remaining in an area pressed by the brush BR after the supply of the cleaning liquid was stopped was sufficiently smaller than an amount of contaminants remaining on another area. Thus, it was confirmed that the smaller the flow rate of the cleaning liquid (the chemical liquid in the present case) to be supplied to the test substrate during the brush pressing movement period, the more improved the cleaning power.

### 9. Effects of Embodiments

In the substrate cleaning device SSR according to the present embodiment, the substrate W that has been carried in is held in a horizontal attitude by the spin chuck 10. Further, the substrate W is rotated by the spin chuck 10 about an axis parallel to the vertical direction. The cleaning liquid is supplied onto the one surface of the substrate W at the reference flow rate rf. Thus, the liquid film L1 of the cleaning liquid is formed on the one surface of the substrate W. Thereafter, during the brush pressing movement period, the brush BR is pressed against the one surface of the substrate W rotated by the spin chuck 10, and the one surface of the substrate W is cleaned.

During at least part of the brush pressing movement period, the flow rate of the cleaning liquid to be supplied to the one surface of the substrate W is lower than the reference flow rate rf, or the cleaning liquid is not supplied to the one surface of the substrate W. In this case, even in a case in which a boundary liquid layer is formed between the brush BR and the one surface of the substrate W due to an occurrence of hydroplaning between the brush BR and the one surface of the substrate W, the thickness of the boundary liquid layer can be decreased as compared with a case in which the cleaning liquid is supplied to the one surface of the substrate W at the reference flow rate rf. Thus, the cleaning power of the brush BR for the one surface of the substrate W is improved. As a result, the cleanliness of the one surface of the substrate W after cleaning is improved. Further, with the above-mentioned configuration, an amount of the cleaning liquid to be used for cleaning the substrate W can be reduced. Therefore, the consumption of the cleaning liquid can be reduced.

Because the brush BR is not pressed against the substrate W during the liquid film formation period, it is not necessary to consider an occurrence of hydroplaning. Therefore, the reference flow rate rf of the cleaning liquid to be supplied to the substrate W during the liquid film formation period is preferably set in consideration of a rotation speed of the substrate W, a viscosity of the cleaning liquid, and the like such that the liquid film formation period can be shortened as much as possible. Because the liquid film formation period is shortened, the throughput of the cleaning process for the substrate W is improved.

### 10. Other Embodiments

(a) While the cleaning liquid is supplied to the substrate W during the liquid film formation period in the substrate cleaning device SSR according to the above-mentioned embodiment, the present invention is not limited to this. During the liquid film formation period, a rinse liquid may be supplied to the substrate W instead of the cleaning liquid.
(b) While the brush BR rotates about the axis extending in the vertical direction (rotates about its axis) during cleaning for the one surface of the substrate W in the substrate cleaning device SSR according to the above-mentioned embodiment, the present invention is not limited to this. The brush BR does not have to rotate about the axis extending in the vertical direction during cleaning for the one surface of the substrate W.
(c) In the substrate cleaning device SSR according to the above-mentioned embodiment, the rotation speed of the substrate W may be suitably changed during the brush pressing movement period. For example, the rotation speed of the substrate W may be decreased continuously or in steps as the brush BR moves from the rotation center position P1 toward the outer peripheral end position P2. Alternatively, the rotation speed of the substrate W may be increased continuously or in steps as the brush BR moves from the rotation center position P1 toward the outer peripheral end position P2.
(d) While the non-circuit forming surface (back surface) of the substrate W is cleaned in the substrate cleaning device SSR according to the above-mentioned embodiment, the present invention is not limited to this. In a case in which the substrate W to be cleaned is a substrate on which a circuit is not formed yet, such as a bare wafer, the circuit forming surface (main surface) of the substrate W may be cleaned by the brush BR in the substrate cleaning device SSR.
(e) While having a circular shape except for a notch in the substrate cleaning device 1 according to the above-mentioned embodiment, the substrate W to be processed may have a rectangular shape.

### 11. Correspondences Between Constituent Elements in Claims and Parts in Preferred Embodiments

In the following paragraphs, non-limiting examples of correspondences between various elements recited in the claims below and those described above with respect to various preferred embodiments of the present invention are explained. As each of various elements recited in the claims, various other elements having configurations or functions described in the claims can be also used.

In the above-mentioned embodiment, the substrate cleaning device SSR is an example of a substrate cleaning device, the spin chuck 10 is an example of a rotation holder, the cleaning liquid nozzle 21 and the cleaning liquid supply system 22 are examples of a liquid supplier, the brush BR is an example of a brush, the brush pressing movement period is an example of a pressing period, the brush pressing mechanism 30 is an example of a brush pressing mechanism, the reference flow rate rf is an example of a reference flow rate, the specific position P3 is an example of a specific position, and the brush separation movement period is an example of a non-pressing period.

Further, the plurality of brush pressing movement periods in FIGS. 9 and 10 are examples of a plurality of pressing periods, the two brush pressing movement periods in FIG. 10 are examples of a first pressing period and a second pressing period, the flow rate af of FIG. 10 is an example of a first flow rate, and the flow rate bf of FIG. 10 is an example of a second flow rate.

### 12. Overview of Embodiments

(Item 1) A substrate cleaning device according to item 1 that cleans one surface of a substrate, includes a rotation holder that rotates the substrate while holding the substrate, a liquid supplier that supplies a cleaning liquid onto the one surface of the substrate held and rotated by the rotation holder, a brush, and a brush pressing mechanism that presses the brush against the one surface of the substrate held and rotated by the rotation holder during a predetermined pressing period, wherein the liquid supplier supplies the cleaning liquid onto the one surface of the substrate at a predetermined reference flow rate before the pressing period, and supplies the cleaning liquid onto the one surface of the substrate at a flow rate smaller than the reference flow rate or stops supplying the cleaning liquid during at least part of the pressing period.

In the substrate cleaning device, the cleaning liquid is supplied onto the one surface of the substrate at the reference flow rate before the pressing period. Thus, a liquid film of the cleaning liquid is formed on the one surface of the substrate. Thereafter, during the pressing period, the brush is pressed against the one surface of the substrate rotated by the rotation holder, and the one surface of the substrate is cleaned.

During at least part of the pressing period, the flow rate of the cleaning liquid to be supplied to the one surface of the substrate W is lower than the reference flow rate, or the cleaning liquid is not supplied to the one surface of the substrate. In this case, even in a case in which a layer of the cleaning liquid is formed between the brush and the one surface of the substrate, the thickness of the layer of the cleaning liquid can be decreased as compared with a case in which the cleaning liquid is supplied to the one surface of the substrate at the reference flow rate. Thus, the cleaning power of the brush for the one surface of the substrate W is improved. As a result, the cleanliness of the one surface of the substrate after cleaning is improved.

Further, with the above-mentioned configuration, an amount of the cleaning liquid to be used for cleaning the substrate can be reduced. Therefore, the consumption of the cleaning liquid can be reduced.
(Item 2) The substrate cleaning device according to item 1, wherein the brush pressing mechanism, during the pressing period, may move the brush from a rotation center of the substrate held and rotated by the rotation holder toward an outer peripheral end of the substrate while pressing the brush against the one surface of the substrate, and the liquid supplier may stop supplying the cleaning liquid during the pressing period.

In this case, the cleaning power of the brush for the one surface of the substrate is further improved in the pressing period. As a result, the cleanliness of the one surface of the substrate after cleaning is further improved.
(Item 3) The substrate cleaning device according to item 1, wherein the brush pressing mechanism, during the pressing period, may move the brush from a rotation center of the substrate held and rotated by the rotation holder toward an outer peripheral end of the substrate while pressing the brush against the one surface of the substrate, and the liquid supplier may supply the cleaning liquid onto the one surface during a period from a start point in time of the pressing period to a point in time at which the brush reaches a specific position between the rotation center and the outer peripheral end from the rotation center, and may stop supplying the cleaning liquid during a period from a point in time at which the brush reaches the specific position to an end point in time of the pressing period.

In this case, the cleaning power of the brush is further improved in the area of the one surface of the substrate to which the cleaning liquid is not supplied and against which the brush is pressed. As a result, the cleanliness of the area including at least the outer peripheral end of the one surface of the substrate after cleaning is further improved.
(Item 4) The substrate cleaning device according to item 1, wherein the pressing period may include a plurality of pressing periods sequentially arranged on a time axis, a predetermined non-pressing period may be set between each two pressing periods adjacent to each other on the time axis among the plurality of pressing periods, the brush pressing mechanism, during each pressing period, may move the brush from a rotation center of the substrate held and rotated by the rotation holder toward an outer peripheral end of the substrate while pressing the brush against the one surface of the substrate, during each non-pressing period, may move the brush from the outer peripheral end toward the rotation center while separating the brush from the one surface of the substrate, and the liquid supplier may stops supplying the cleaning liquid during each pressing period, and may supply the cleaning liquid onto the one surface of the substrate during each non-pressing period.

In this case, the cleaning power of the brush for the one surface of the substrate is further improved in each pressing period. Further, the one surface of the substrate is cleaned by the brush multiple times. As a result, the cleanliness of the one surface of the substrate after cleaning is further improved.
(Item 5) The substrate cleaning device according to item 1, wherein the pressing period may include a first pressing period and a second pressing period that are sequentially arranged on a time axis, a predetermined non-pressing period may be set between the first pressing period and the second pressing period, the brush pressing mechanism, during each of the first pressing period and the second pressing period, may move the brush from a rotation center of the substrate held and rotated by the rotation holder toward an outer peripheral end of the substrate while pressing the brush against the one surface of the substrate, and during the non-pressing period, may move the brush from the outer peripheral end toward the rotation center while separating the brush from the one surface of the substrate, and the liquid supplier may supply the cleaning liquid onto the one surface of the substrate at a first flow rate smaller than the reference flow rate during the first pressing period, and may supply the cleaning liquid onto the one surface of the substrate at a second flow rate larger than the first flow rate during the second pressing period.

In this case, because the cleaning liquid is supplied onto the one surface of the substrate at the first flow rate in the first pressing period, the cleaning power of the brush for the one surface of the substrate is further improved. Thereafter, in the second pressing period, the cleaning liquid is supplied onto the one surface of the substrate at the second flow rate larger than the first flow rate. Thus, even in a case in which remaining on the one surface of the substrate, contaminants that have been stripped by the brush during the first pressing period are smoothly washed away by a large amount of the cleaning liquid. As a result, the cleanliness of the one surface of the substrate after cleaning is further improved.
(Item 6) A substrate cleaning method according to item 6 of cleaning one surface of a substrate, includes the steps of rotating the substrate while holding the substrate using a rotation holder, supplying a cleaning liquid onto the one surface of the substrate held and rotated by the rotation holder, and pressing a brush against the one surface of the substrate held and rotated by the rotation holder during a predetermined pressing period, wherein the step of supplying a cleaning liquid includes supplying the cleaning liquid onto the one surface of the substrate at a predetermined reference flow rate before the pressing period, and supplying the cleaning liquid onto the one surface of the substrate at a flow rate smaller than the reference flow rate or stopping supplying the cleaning liquid during at least part of the pressing period.

With the substrate cleaning method, the cleaning liquid is supplied onto the one surface of the substrate at the reference flow rate before the pressing period. Thus, the liquid film of the cleaning liquid is formed on the one surface of the substrate. Thereafter, during the pressing period, the brush is pressed against the one surface of the substrate rotated by the rotation holder, and the one surface of the substrate is cleaned.

During at least part of the pressing period, the flow rate of the cleaning liquid to be supplied to the one surface of the substrate W is lower than the reference flow rate, or the cleaning liquid is not supplied to the one surface of the substrate W. In this case, even in a case in which a layer of the cleaning liquid is formed between the brush and the one surface of the substrate, the thickness of the layer of the cleaning liquid can be decreased as compared with a case in which the cleaning liquid is supplied to the one surface of the substrate at the reference flow rate. Thus, the cleaning power of the brush for the one surface of the substrate is improved. As a result, the cleanliness of the one surface of the substrate after cleaning is improved.

Further, with the above-mentioned configuration, an amount of the cleaning liquid to be used for cleaning the substrate can be reduced. Therefore, the consumption of the cleaning liquid can be reduced.
(Item 7) The substrate cleaning method according to item 6, wherein the step of pressing may include, during the pressing period, moving the brush from a rotation center of the substrate held and rotated by the rotation holder toward an outer peripheral end of the substrate while pressing the brush against the one surface of the substrate, and the step of supplying a cleaning liquid may include stopping supplying the cleaning liquid during the pressing period.

In this case, the cleaning power of the brush for the one surface of the substrate is further improved in the pressing period. As a result, the cleanliness of the one surface of the substrate after cleaning is further improved.
(Item 8) The substrate cleaning method according to item 6, wherein the step of pressing may include, during the pressing period, moving the brush from a rotation center of the substrate held and rotated by the rotation holder toward an outer peripheral end of the substrate while pressing the brush against the one surface of the substrate, and the step of supplying a cleaning liquid may include supplying the cleaning liquid onto the one surface during a period from a start point in time of the pressing period to a point in time at which the brush reaches a specific position between the rotation center and the outer peripheral end from the rotation center, and stopping supplying the cleaning liquid during a period from a point in time at which the brush reaches the specific position to an end point in time of the pressing period.

In this case, the cleaning power of the brush is further improved in the area of the one surface of the substrate to which the cleaning liquid is not supplied and against which the brush is pressed. As a result, the cleanliness of the area including at least the outer peripheral end of the one surface of the substrate after cleaning is further improved.
(Item 9) The substrate cleaning method according to item 6, wherein the pressing period may include a plurality of pressing periods sequentially arranged on a time axis, a predetermined non-pressing period may be set between each two pressing periods adjacent to each other on the time axis among the plurality of pressing periods, the step of pressing may include, during each pressing period, moving the brush from a rotation center of the substrate held and rotated by the rotation holder toward an outer peripheral end of the substrate while pressing the brush against the one surface of the substrate, and during each non-pressing period, moving the brush from the outer peripheral end toward the rotation center while separating the brush from the one surface of the substrate, and the step of supplying a cleaning liquid may include stopping supplying the cleaning liquid during each pressing period, and supplying the cleaning liquid onto the one surface of the substrate during each non-pressing period.

In this case, the cleaning power of the brush for the one surface of the substrate is further improved in each pressing period. Further, the one surface of the substrate is cleaned by the brush multiple times. As a result, the cleanliness of the one surface of the substrate after cleaning is further improved.
(Item 10) The substrate cleaning method according to item 6, wherein the pressing period may include a first pressing period and a second pressing period that are sequentially arranged on a time axis, a predetermined non-pressing period may be set between the first pressing period and the second pressing period, the step of pressing may include, during each of the first pressing period and the second pressing period, moving the brush from a rotation center of the substrate held and rotated by the rotation holder toward an outer peripheral end of the substrate while pressing the brush against the one surface of the substrate, and during the non-pressing period, moving the brush from the outer peripheral end toward the rotation center while separating the brush from the one surface of the substrate, and the step of supplying a cleaning liquid may include supplying the cleaning liquid onto the one surface of the substrate at a first flow rate smaller than the reference flow rate during the first pressing period, and supplying the cleaning liquid onto the one surface of the substrate at a second flow rate larger than the first flow rate during the second pressing period.

In this case, because the cleaning liquid is supplied onto the one surface of the substrate at the first flow rate in the first pressing period, the cleaning power of the brush for the one surface of the substrate is further improved. Thereafter, in the second pressing period, the cleaning liquid is supplied onto the one surface of the substrate at the second flow rate larger than the first flow rate. Thus, even in a case in which remaining on the one surface of the substrate, contaminants that have been stripped by the brush during the first pressing period are smoothly washed away by a large amount of the cleaning liquid. As a result, the cleanliness of the one surface of the substrate after cleaning is further improved.

With the substrate cleaning device according to a series of above-mentioned embodiments, the cleanliness of the substrate after cleaning using the brush is improved, so that the throughput yield of products obtained by the substrate process is improved. Thus, because the wasteful substrate process is reduced, energy can be saved for the substrate process. Further, because utilization of a wasteful chemical liquid or the like can be reduced, it can contribute to a reduction in pollution of a global environment.

1. A substrate cleaning device that cleans one surface of a substrate, comprising:
a rotation holder that rotates the substrate while holding the substrate;
a liquid supplier that supplies a cleaning liquid onto the one surface of the substrate held and rotated by the rotation holder;
a brush; and
a brush pressing mechanism that presses the brush against the one surface of the substrate held and rotated by the rotation holder during a predetermined pressing period, wherein
the liquid supplier
supplies the cleaning liquid onto the one surface of the substrate at a predetermined reference flow rate before the pressing period, and
supplies the cleaning liquid onto the one surface of the substrate at a flow rate smaller than the reference flow rate or stops supplying the cleaning liquid during at least part of the pressing period.

2. The substrate cleaning device according to claim 1, wherein
the brush pressing mechanism, during the pressing period, moves the brush from a rotation center of the substrate held and rotated by the rotation holder toward an outer peripheral end of the substrate while pressing the brush against the one surface of the substrate, and
the liquid supplier stops supplying the cleaning liquid during the pressing period.

3. The substrate cleaning device according to claim 1, wherein
the brush pressing mechanism, during the pressing period, moves the brush from a rotation center of the substrate held and rotated by the rotation holder toward an outer peripheral end of the substrate while pressing the brush against the one surface of the substrate, and
the liquid supplier
supplies the cleaning liquid onto the one surface during a period from a start point in time of the pressing period to a point in time at which the brush reaches a specific position between the rotation center and the outer peripheral end from the rotation center, and
stops supplying the cleaning liquid during a period from a point in time at which the brush reaches the specific position to an end point in time of the pressing period.

4. The substrate cleaning device according to claim 1, wherein
the pressing period includes a plurality of pressing periods sequentially arranged on a time axis,
a predetermined non-pressing period is set between each two pressing periods adjacent to each other on the time axis among the plurality of pressing periods,
the brush pressing mechanism,
during each pressing period, moves the brush from a rotation center of the substrate held and rotated by the rotation holder toward an outer peripheral end of the substrate while pressing the brush against the one surface of the substrate,
during each non-pressing period, moves the brush from the outer peripheral end toward the rotation center while separating the brush from the one surface of the substrate, and
the liquid supplier
stops supplying the cleaning liquid during each pressing period, and
supplies the cleaning liquid onto the one surface of the substrate during each non-pressing period.

5. The substrate cleaning device according to claim 1, wherein
the pressing period includes a first pressing period and a second pressing period that are sequentially arranged on a time axis,
a predetermined non-pressing period is set between the first pressing period and the second pressing period,
the brush pressing mechanism,
during each of the first pressing period and the second pressing period, moves the brush from a rotation center of the substrate held and rotated by the rotation holder toward an outer peripheral end of the substrate while pressing the brush against the one surface of the substrate, and
during the non-pressing period, moves the brush from the outer peripheral end toward the rotation center while separating the brush from the one surface of the substrate, and
the liquid supplier
supplies the cleaning liquid onto the one surface of the substrate at a first flow rate smaller than the reference flow rate during the first pressing period, and
supplies the cleaning liquid onto the one surface of the substrate at a second flow rate larger than the first flow rate during the second pressing period.

6. A substrate cleaning method of cleaning one surface of a substrate, including the steps of:
rotating the substrate while holding the substrate using a rotation holder;
supplying a cleaning liquid onto the one surface of the substrate held and rotated by the rotation holder; and
pressing a brush against the one surface of the substrate held and rotated by the rotation holder during a predetermined pressing period, wherein
the step of supplying a cleaning liquid includes
supplying the cleaning liquid onto the one surface of the substrate at a predetermined reference flow rate before the pressing period, and
supplying the cleaning liquid onto the one surface of the substrate at a flow rate smaller than the reference flow rate or stopping supplying the cleaning liquid during at least part of the pressing period.

7. The substrate cleaning method according to claim 6, wherein
the step of pressing includes, during the pressing period, moving the brush from a rotation center of the substrate held and rotated by the rotation holder toward an outer peripheral end of the substrate while pressing the brush against the one surface of the substrate, and
the step of supplying a cleaning liquid includes stopping supplying the cleaning liquid during the pressing period.

8. The substrate cleaning method according to claim 6, wherein
the step of pressing includes, during the pressing period, moving the brush from a rotation center of the substrate held and rotated by the rotation holder toward an outer peripheral end of the substrate while pressing the brush against the one surface of the substrate, and
the step of supplying a cleaning liquid includes
supplying the cleaning liquid onto the one surface during a period from a start point in time of the pressing period to a point in time at which the brush reaches a specific position between the rotation center and the outer peripheral end from the rotation center, and
stopping supplying the cleaning liquid during a period from a point in time at which the brush reaches the specific position to an end point in time of the pressing period.

9. The substrate cleaning method according to claim 6, wherein
the pressing period includes a plurality of pressing periods sequentially arranged on a time axis,
a predetermined non-pressing period is set between each two pressing periods adjacent to each other on the time axis among the plurality of pressing periods,
the step of pressing includes,
during each pressing period, moving the brush from a rotation center of the substrate held and rotated by the rotation holder toward an outer peripheral end of the substrate while pressing the brush against the one surface of the substrate, and
during each non-pressing period, moving the brush from the outer peripheral end toward the rotation center while separating the brush from the one surface of the substrate, and
the step of supplying a cleaning liquid includes
stopping supplying the cleaning liquid during each pressing period, and
supplying the cleaning liquid onto the one surface of the substrate during each non-pressing period.

10. The substrate cleaning method according to claim 6, wherein
the pressing period includes a first pressing period and a second pressing period that are sequentially arranged on a time axis,
a predetermined non-pressing period is set between the first pressing period and the second pressing period,
the step of pressing includes,
during each of the first pressing period and the second pressing period, moving the brush from a rotation center of the substrate held and rotated by the rotation holder toward an outer peripheral end of the substrate while pressing the brush against the one surface of the substrate, and
during the non-pressing period, moving the brush from the outer peripheral end toward the rotation center while separating the brush from the one surface of the substrate, and
the step of supplying a cleaning liquid includes
supplying the cleaning liquid onto the one surface of the substrate at a first flow rate smaller than the reference flow rate during the first pressing period, and
supplying the cleaning liquid onto the one surface of the substrate at a second flow rate larger than the first flow rate during the second pressing period.
